(19) United States
(12) Patent Application Publication
(10) Pub. No.: US 2020/0248811 A1
(43) Pub. Date: Aug. 6, 2020

(54) Seal Structure

(71) Applicant: Hitachi Automotive Systems, Ltd., Hitachinaka-shi, lbaraki (JP)

(72) Inventors: Tetsuya FUKUYAMA, Tokyo (JP); Norio ISHITSUKA, Tokyo (JP); Takuro KANAZAWA, Hitachinaka-shi (JP)

(21) Appl. No.: 16/641,890

(22) PCT Filed: Apr. 10, 2018
(86) PCT No.: PCT/JP2018/015033

§ 371 Date: Feb. 25, 2020

(30) Foreign Application Priority Data
Aug. 30, 2017 (JP) 2017-165133

(51) Int. Cl. F16J 15/14; F16J 15/06

(52) U.S. Cl. CPC F16J 15/14; H05K 5/061; F16J 15/062

(57) ABSTRACT

An object of the present invention is to provide a seal structure capable of maintaining necessary sealing performance for a long period of time even in an environment where a corrosive solution such as salt water adheres. A seal portion at which seal materials are formed and a fixing portion that fixes a housing and a cover to each other are formed at a joint portion between the housing and the cover constituting a casing. The seal portion and the fixing portion are arranged from an outer edge portion side of the joint portion toward an inside of the casing in order of the seal portion and the fixing portion.

### TECHNICAL FIELD

The present invention relates to a seal structure for a plurality of casing members constituting a casing.

### BACKGROUND ART

For example, a configuration in which a circuit board having each electronic component mounted thereon is accommodated in a space formed by assembling and joining a plurality of casing members (for example, a housing and a cover) in an electronic control device mounted on an electric power steering apparatus of a vehicle is known as a seal structure of an electromechanical integrated device on which an electronic component is mounted.

Since the electronic control device of the electric power steering apparatus is disposed near an engine room and is used in an environment in which there is rainwater around, the seal structure obtained by assembling and joining the plurality of casing members needs to be a highly reliable structure that ensures airtightness and waterproof.

As a seal structure of a pair of casing members (for example, a pair of casing members arranged and joined so as to face each other) joined to each other among the casing members, there is a structure in which joint surfaces of joint portions of both the casing members are sealed (for example, end surfaces of opening portions formed in both the casing members are sealed). As such a seal structure, there is a structure described in JP 2016-35491 A (PTL 1).

PTL 1 discloses a seal structure of an optical module having an optical component mounted thereon. In this seal structure, a pedestal (301) on which an optical component (314) is mounted, and a module cover (306) that seals the optical component (314) in combination with the pedestal (301). The pedestal (301) and module cover (306) are sealed by an O-ring (302) and a liquid seal material (304) (see Summary of Invention). A groove portion (305) for coating the liquid seal material (304) is formed in the pedestal (301), and a stepped portion (303) for disposing the O-ring (302) is formed on an inner peripheral side of the groove portion (305) (paragraphs 0019 and 0028). After the liquid seal material (304) is coated on the groove portion (305), the module cover (306) and the pedestal (301) are fitted together, and the pedestal (301) and the module cover (306) are combined by using a screw (307) (paragraph 0036). Receiving portions (350 and 351) facing the module cover (306) and the pedestal (301) are formed, and the module cover receiving portion (350) and the pedestal receiving portion (351) are formed on flat surfaces (paragraph 0025). The module cover receiving portion (350) and the pedestal receiving portion (351) are arranged on an outer edge side with respect to the seal portions of the O-ring (302) and the liquid seal material (304), and fastening portions are formed in the module cover receiving portion (350) and the pedestal receiving portion (351) by the screw (307) (see FIG. 4).

In the above description, a reference sign in parentheses is used in PTL 1, and is different from a reference sign in the present specification and the drawings attached to the present specification.

### CITATION LIST

### Patent Literature

PTL 1: JP 2016-35491 A

### SUMMARY OF INVENTION

### Technical Problem

In the seal structure of PTL 1, the fastening portions by the screw formed at the module cover receiving portion and the pedestal receiving portion are arranged on the outer edge side with respect to the seal portions of the O-ring and the liquid seal material. That is, in the seal structure of PTL1, the fastening portions using the screw, the seal portions using the liquid seal material, and the seal portions using the O-ring are arranged in this order from the outer edge side of the module cover and the pedestal. The seal structure of PTL 1 is applied to the optical module, and it is not assumed that a corrosive solution such as salt water enters a gap portion between the module cover receiving portion and the pedestal receiving portion at the fastening portions using the screw.

In an electronic control device of an electric power steering apparatus of a vehicle, when the corrosive solution such as salt water enters the gap portion between the cover and the housing in the structure in which the plurality of casing members (for example, the housing and the cover) are assembled, there is a possibility that crevice corrosion will occur in the gap portion between the cover and the housing. When the crevice corrosion occurs, there is a possibility that airtight defect or fixing defect will occur in the electronic device by reducing a thickness of the gap portion.

An object of the present invention is to provide a seal structure capable of maintaining necessary sealing performance for a long period of time even in an environment where a corrosive solution such as salt water adheres.

### Solution to Problem

In order to achieve the object, an electronic device of the present invention includes a seal portion at which a seal material is formed, and a fixing portion that fixes a housing and a cover to each other at a joint portion between the housing and the cover constituting a casing. The seal portion and the fixing portion are arranged from the position close to an outer edge portion of the joint portion in order of the seal portion and the fixing portion.

### Advantageous Effects of Invention

According to the present invention, since the seal portion is disposed on the outer edge side with respect to the fixing portion, it is possible to maintain the necessary sealing performance for a long period of time even in the environment in which the corrosive solution such as salt water adheres. Other objects, configurations, and effects will be made apparent in the following descriptions.

### BRIEF DESCRIPTION OF DRAWINGS

FIG. 1 is a perspective view illustrating an external appearance of an electronic device according to an embodiment of the present invention.

FIG. 2 is a schematic diagram illustrating an embodiment of a seal structure according to the present invention, and is a cross-sectional view illustrating a II-II cross section of the electronic device of FIG. 1.

FIG. 3 is a schematic diagram illustrating another embodiment (second embodiment) of the seal structure according to the present invention, and is a cross-sectional view illustrating the II-II cross section of the electronic device of FIG. 1.

FIG. 4 is a schematic diagram illustrating another embodiment (third embodiment) of the seal structure according to the present invention, and is a cross-sectional view illustrating the II-II cross section of the electronic device of FIG. 1.

FIG. 5 is a schematic diagram illustrating a modification example of a damming portion in the seal structure (third embodiment) according to the present invention, and is a cross-sectional view illustrating the II-II cross section of the electronic device of FIG. 1.

### DESCRIPTION OF EMBODIMENTS

Hereinafter, embodiments of the present invention will be appropriately described in detail with reference to the drawings.

### First Embodiment

In the present embodiment, an example in which a seal structure according to the embodiment of the present invention is applied to an electric power steering apparatus which is an example of an electromechanical integrated device in which an electronic device having an electronic component mounted thereon and a mechanical device are integrated will be described. The seal structure according to the present invention can be applied to devices other than the electric power steering apparatus, and is particularly suitable for devices requiring both airtightness and waterproofness and fixation.

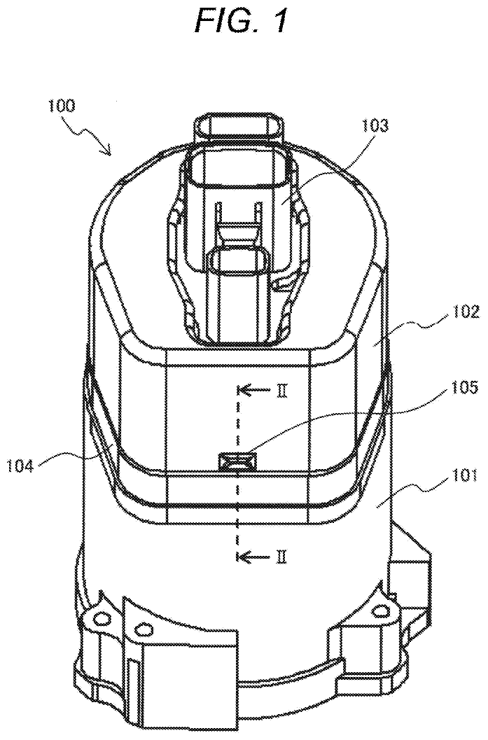

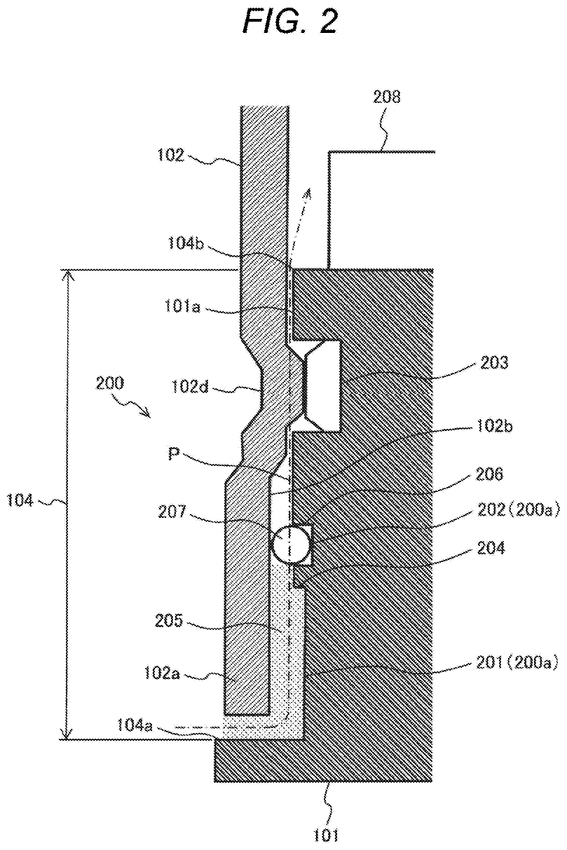

The electric power steering apparatus of the present embodiment will be described with reference to FIGS. 1 and 2.

FIG. 1 is a perspective view illustrating an appearance of an electronic device according to the embodiment of the present invention.

An electronic device 100 of the electric power steering apparatus includes a housing 101 on which an electronic component 208 (see FIG. 2) is mounted, a cover 102 that protects the electronic component, a connector 103, a joint portion 104 between the housing 101 and the cover 102, and a caulking and fixing portion 105 of the housing 101 and the cover 102. The housing 101 and the cover 102 constitute a casing that accommodates the electronic component 208. That is, in the present embodiment, the casing is constituted by the two casing members 101 and 102. The housing 101 constitutes a base member on which the electronic component 208 is disposed.

The electric power steering apparatus including the electronic device 100 is mounted on a vehicle, and is placed in an environment in which a corrosive solution such as salt water adheres. The electronic device 100 has a control function of the electric power steering apparatus.

FIG. 2 is a schematic diagram illustrating an embodiment of the seal structure according to the present invention, and is a cross-sectional view illustrating a II-II cross section of the electronic device of FIG. 1.

The seal structure of the present embodiment includes a liquid seal portion 201, a solid seal portion 202, a fixing portion 203, a groove portion 204 for liquid seal, a liquid seal material 205, a groove portion 206 for solid seal, a solid seal material 207, and the electronic component 208. Since the electric power steering apparatus is placed in the environment in which the corrosive solution such as salt water adheres, a seal structure 200 of the electronic device 100 needs to maintain airtightness and waterproofness and a fixing function for a long period of time.

The seal structure 200 of the electronic device 100 according to the present embodiment is a seal structure of the joint portion 104 that joins the housing 101 on which the electronic component 208 is mounted and the cover 102 that protects the electronic component 208. An end portion (outer edge portion) 102a of the cover 102 is fit to an outer peripheral portion 101a of the housing 101 such that an inner peripheral surface 102b of the end portion (outer edge portion) 102a of the cover 102 faces an outer peripheral surface 101a of the housing 101, and thus, the cover 102 is assembled to the housing 101 at the joint portion 104.

The inner peripheral surface 102b of the cover 102 and the outer peripheral surface 101a of the housing 101 are constituted by surfaces along a fitting direction of the cover 102 and the housing 101. Thus, in order to constitute the joint portion 104, it is possible to decrease a dimension in a radial direction compared to a case where the facing surfaces of the cover 102 and the housing 101 protrude in a direction perpendicular to the fitting direction of the cover 102 and the housing 101. This is advantageous for reducing the size of the device as the electronic device of the electric power steering apparatus.

When the seal structure 200 is not provided at the joint portion 104, an upstream end portion of a path P through which a liquid enters the inside of the electronic device 100 is referred to as an outer edge portion 104a. An end portion inside the joint portion 104 is referred to as an inner end portion 14b.

The liquid seal portion 201, the solid seal portion 202, and the fixing portion 203 are arranged in the seal structure 200 formed at the joint portion 104 in order of the liquid seal portion 201, the solid seal portion 202, and the fixing portion 203 from a position close to the outer edge portion 104a of the joint portion 104. That is, in the seal structure 200, the liquid seal portion 201, the solid seal portion 202, and the fixing portion 203 are arranged in order of the liquid seal portion 201, the solid seal portion 202, and the fixing portion 203 from the outer edge portion 104a side of the joint portion 104 toward the inside of the casing (the inner end portion 14b of the joint portion 104).

In particular, a seal portion 200a includes the liquid seal portion 201 and the solid seal portion 202, and is a portion at which the seal materials such as the liquid seal material 205 and the solid seal material 207 are provided.

The liquid seal portion 201 is formed by forming the groove portion 204 for liquid seal in a circumferential shape along the joint portion 104 between the housing 101 and the cover 102 and filling the groove portion 204 with the liquid seal material 205. The liquid seal portion 201 and the groove portion 204 are formed on the entire circumference of the housing 101. In the present embodiment, the groove portion 204 is formed on the housing 101 side. The liquid seal material 205 is cured after the cover 102 is assembled to the housing 101.

The liquid seal portion 201 is disposed at a position closest to the outer edge portion 104a of the joint portion 104 on the entrance path P, and thus, a liquid such as water is prevented from entering the inside of the seal structure on which the electronic component 208 is mounted from the outside of the seal structure. As a result, it is possible to maintain the airtightness inside the seal structure. A liquid gasket such as FIPG can be used as the liquid seal material 205.

The solid seal portion 202 is disposed on the entrance path P at a position closer to the electronic component 208 than the liquid seal portion 201. The groove portion 206 for the solid seal portion 202 is formed in a peripheral portion of the housing 101, and the solid seal material 207 is disposed. The solid seal portion 202 and the groove portion 206 are formed on the entire circumference of the housing 101. The solid seal material 207 is disposed on the entrance path P at the position closer to the electronic component 208 than the liquid seal portion 201, and thus, the liquid seal material 205 can be prevented from entering in a direction of the electronic component 208 due to liquid dripping at the time of assembling the cover 102 to the housing 101. That is, the solid seal material 207 constitutes a damming portion for damming the liquid seal material 205. Accordingly, it is possible to secure an appropriate amount of the liquid seal material 205 in the groove portion 204 for the liquid seal portion 201. An O-ring or a gasket can be used as the solid seal material 205.

The fixing portion 203 fixes the housing 101 and the cover 102 by caulking (plastically deforming) the cover 102 that protects the electronic component and pressing a wall portion of the housing 101 on which the electronic component is mounted. Thus, it is possible to fix the housing 101 and the cover 102 without using bolts or adhesives, and it is possible to expect the size reduction of the electric power steering and the simplification of a manufacturing process. The fixing portion 203 may fix the housing and the cover through shrink-fitting or press-fitting. Although the size reduction and the simplification of the manufacturing process are inferior to the caulking, the fixing portion 203 may be formed by fastening the caulking position with a bolt.

### Second Embodiment

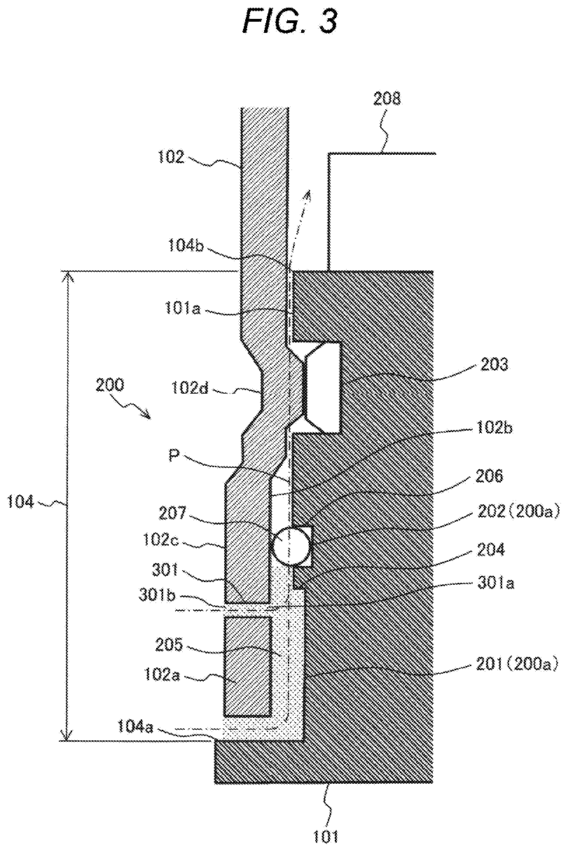

A second embodiment will be described with reference to FIG. 3. FIG. 3 is a schematic diagram illustrating another embodiment (second embodiment) of the seal structure according to the present invention, and is a cross-sectional view illustrating a II-II cross section of the electronic device of FIG. 1. The same configurations as those in the first embodiment will be assigned the same reference signs as those in the first embodiment, and description thereof will be omitted.

In the present embodiment, as illustrated in FIG. 3, in order to confirm a filling state of the liquid seal material 205, a through hole 301 penetrating through the cover 102 in a thickness direction (a plate thickness direction in which an outer peripheral surface 102c side and an inner peripheral surface 102b side are connected) is formed at a portion of the cover 102 constituting the joint portion 104. The configuration other than the through hole 301 is the same as that of the first embodiment.

The through hole 301 is formed at the joint portion 104 between the housing 101 and the cover 102 such that the inside of the through hole 301 is visible. The through hole 301 is formed such that an opening surface on the inner peripheral surface 102b side of the cover 102 faces the groove portion 204 of the liquid seal portion 201. That is, the opening surface 301a of the through hole 301 on the inner peripheral surface 102b side of the cover 102 is located closer to the outer edge portion 104a side of the joint portion 104 than the solid seal portion 202 (solid seal material 207). Further, an opening surface 301a of the through hole 301 is located on the outer edge portion 104a side of the joint portion 104 than the end portion on the solid seal portion 202 side of the liquid seal portion 201 (liquid seal material 205).

In the present embodiment, the penetrating direction of the through hole 301 is perpendicular to the inner peripheral surface 102b and the outer peripheral surface 102c of the cover 102. However, the penetrating direction of the through hole 301 may be inclined with respect to the direction perpendicular to the inner peripheral surface 102b and the outer peripheral surface 102c.

The through hole 301 has an opening surface opened in the outer peripheral surface 102c of the cover 102, and thus, the filling state of the liquid seal material 205 can be confirmed through the opening surface. A method for confirming the filling state of the liquid seal material 205 will be described. The through hole 301 is formed in the cover 102 in advance, and when the cover 102 is attached in a state where the groove portion 204 of the liquid seal portion 201 is filled with the liquid seal material 205, the liquid seal material 205 fills between the housing 101 and the cover 102. The liquid seal material 205 filling the liquid seal portion 201 overflows from the through hole 301. Therefore, it is possible to confirm a state (groove filling state) in which the liquid seal material 205 fills the liquid seal portion 201 by confirming the state in which the liquid seal material 205 overflows from the through hole 301.

According to the present embodiment, it is possible to easily confirm the filling state of the liquid seal material 205 in a process of assembling the cover 102. Therefore, the reliability of the electronic device and the electric power steering apparatus is increased.

The liquid seal material 205 does not need to overflow to the outside of the through hole 301 in the groove filling state, and may flow into the through hole 301 from the opening surface of the through hole 301 on the inner peripheral surface 102b side of the cover 102. However, the through hole 301 constitutes the path P through which the liquid enters, as illustrated in FIG. 3. Thus, it is preferable that the liquid seal material 205 is reliably flown into the through hole 301. As the liquid seal material 205 becomes closer to the opening surface 301b of the through hole 301 opened in the outer peripheral surface 102c of the cover 102, the sealing performance is improved. In the present embodiment, a coating amount (filling amount) of the liquid seal material 205 is set such that a height of the liquid seal material 205 within the through hole 301 is the same as the opening surface 301b of the through hole 301 or the liquid seal material 205 slightly overflows from the opening surface 301b of the through hole 301.

The through hole 301 has a shape in which the liquid seal material 205 fills between the housing 101 and the cover 102 by penetrating through the cover 102 from the outer peripheral surface 102c side of the cover 102 and is communicatively connected to the groove portion 204 for liquid seal. The number of through holes 301 is not limited to one, and a plurality of through holes may be formed on the circumference at intervals.

When the plurality of through holes 301 is formed on the circumference at intervals, it is possible to confirm that the circumferential groove portion 204 for liquid seal is filled with the liquid seal material 205, and it is possible to contribute to improving the airtightness and waterproofing of the seal portion.

When the viscosity of the liquid seal material 205 is high, the liquid seal material 205 stays in the groove portion 204 for liquid seal portion, and thus, it is possible to secure an appropriate amount of the liquid seal material 205 in the groove portion 204 for liquid seal. Accordingly, the liquid such as water can be prevented from entering the inside of the electronic device 100 on which the electronic component 208 is mounted from the outside of the seal structure 200, and it is possible to maintain the airtightness within the electronic device 100 (within the seal structure 200) on which the electronic component 208 is mounted.

### Third Embodiment

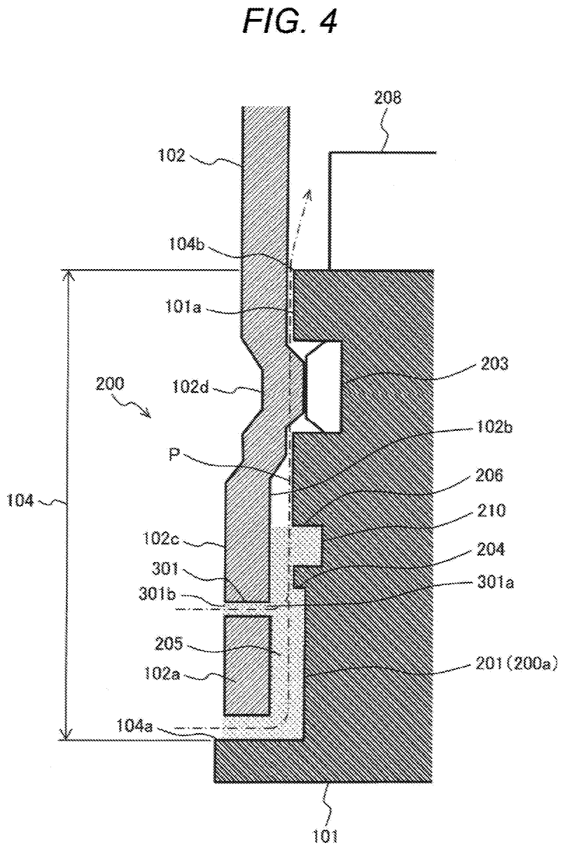

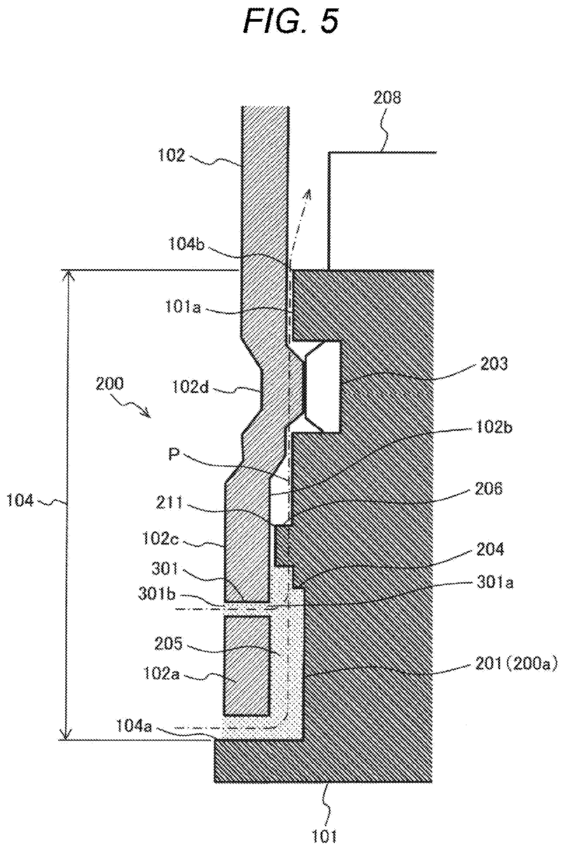

A third embodiment will be described with reference to FIGS. 4 and 5. FIG. 4 is a schematic diagram illustrating another embodiment (third embodiment) of the seal structure according to the present invention, and is a cross-sectional view illustrating a II-II cross section of the electronic device of FIG. 1. The same configurations as those in the first and second embodiments will be assigned the same reference signs as those in the first and second embodiments, and description thereof will be omitted.

In the present embodiment, the solid seal material 207 of the first and second embodiments is not formed. Instead, a groove portion 210 is formed at a portion at which the solid seal material 207 is disposed in the first and second embodiments in order to prevent the liquid seal material 205 from entering in the direction of the electronic component 208 due to the liquid dripping. The groove portion 210 constitutes a damming portion for damming the liquid seal material 205.

The seal portion 200a of the present embodiment is constituted by a liquid seal portion 201 and a groove portion 210 constituting a damming portion.

In order to dam the liquid seal material 205, the groove portion 210 is formed such that a depth thereof is deeper than a depth of the groove portion 204 for liquid seal. That is, a depth dimension of the groove portion 210 is larger than a depth dimension of the groove portion 204 for liquid seal.

The groove portion 210 is formed in a range of a circumferential direction of the housing 101 at which at least the liquid seal material 205 of the liquid seal portion 201 is disposed, and the groove portion 210 is formed on the entire circumference of the housing 101 in the present embodiment.

FIG. 5 is a schematic diagram illustrating a modification example of the damming portion in the seal structure (third embodiment) according to the present invention, and is a cross-sectional view illustrating a II-II cross section of the electronic device of FIG. 1. The same configurations as those in the first and second embodiments will be assigned the same reference signs as those in the first and second embodiments, and description thereof will be omitted.

In the present modification example, a projecting portion 211 that protrudes from the outer peripheral surface of the housing 1 toward the cover 102 is formed instead of the groove portion 210 of FIG. 4. In the present modification example, the projecting portion 211 constitutes the damming portion of the liquid seal material 205.

The seal portion 200a of the present modification example is constituted by the liquid seal portion 201 and the projecting portion 211 constituting the damming portion.

The projecting portion 211 is formed in a range of the circumferential direction of the housing 101 at which at least the liquid seal material 205 of the liquid seal portion 201 is disposed, and is formed on the entire circumference of the housing 101 in the present embodiment.

In the present embodiment, the liquid seal portion 201, the damming portions 210 and 211, and the fixing portion 203 are arranged in the seal structure 200 formed in the joint portion 104 from the position close to the outer edge portion 104a of the joint portion 104 in order of the liquid seal portion 201, the damming portions 210 and 211, and the fixing portion 203. That is, the liquid seal portion 201, the damming portions 210 and 211, and the fixing portion 203 are arranged in the seal structure 200 from the outer edge portion 104a side of the joint portion 104 toward the inside of the casing (the inner end portion 14b of the joint portion 104) in order of the seal portion 201, the damming portions 210 and 211, and the fixing portion 203.

Due to the seal structure 200 of the aforementioned embodiments, it is possible to prevent the corrosive solution such as salt water from adhering to a gap portion of the joint portion 104 between the cover 102 and the housing 101, and it is possible to suppress or prevent the occurrence of crevice corrosion. Accordingly, it is possible to suppress or prevent airtight defect or fixing defect of the electronic device by reducing the thickness of the gap portion. Thus, the sealing structure of the present invention can maintain necessary sealing performance for a long period of time even in the environment in which the corrosive solution such as salt water adheres.

In the aforementioned embodiments, the fixing portion 203 is a fixing structure that plastically deforms the cover 102 such as caulking.

That is, the fixing portion 203 fixes the cover 102 to the housing 101 by pressing a plastic deformation portion 102d obtained by plastically deforming the cover 102 against the wall portion of the housing 101. Thus, the through hole is not formed in the cover 102, and a communication portion which is communicatively connected to the outside is not formed on the electronic component 208 side with respect to the seal portion 200a. Thus, it is possible to improve the sealing performance and airtightness of the electronic device 100.

In the aforementioned embodiments, the fixing portion 203 is formed along the outer peripheral surface 102c of the cover 102, and the projecting portion that protrudes outward from the outer peripheral surface 102c is not formed. That is, the fixing portion 203 is disposed on the outer peripheral surface 102c of the cover 102. Thus, it is possible to reduce the size of the electronic device 100, and it is possible to achieve a structure with few components interfering with other components of the electric power steering apparatus (mechanical and electric integrated device). Thus, it is possible to increase a design freedom of the electric power steering apparatus.

In the liquid seal material 205, since the liquid material adheres, the airtightness is increased regardless of the size and variation of a non-coated component such as the housing 101. However, the total inspection of the coating width and height of the liquid seal material 205 cannot be performed at the joint portion 104 between the housing 101 and the cover 102 in the manufacturing process. Thus, the coating quality of the liquid seal material 205 is unknown. In the embodiments according to the present invention, the through hole 301 is formed, and thus, it is possible to confirm the coating quality of the liquid seal material 205. Further, it is possible to suppress or prevent a reduction in yield due to the airtightness defect of the joint portion 104 between the housing 101 and the cover 102. It is possible to confirm a curing state of the liquid seal material 205 from the outside of the joint portion 104 between the housing 101 and the cover 102.

The liquid seal material 205 becomes solid by being cured, but is referred to as the liquid seal material depending on a state before being cured. The liquid seal portion 201 is a portion at which the liquid seal material 205 is cured, and can be referred to as a liquid seal material cured portion.

The present invention is not limited to the aforementioned embodiments, and includes various modification examples. For example, the aforementioned embodiments are described in detail in order to facilitate easy understanding of the present invention, and are not limited to necessarily include all the components. Some of the components of a certain embodiment can be substituted into the components of another embodiment, and the components of another embodiment can be added to the component of a certain embodiment. Additions, the components of another embodiment can be added, removed, and substituted to, from, and into some of the components of the aforementioned embodiments.

### REFERENCE SIGNS LIST

100 electronic device
101 housing on which electronic component is mounted
102 cover protecting electronic component
102d plastic deformation portion (caulking portion) in which cover 102 is plastically deformed
103 connector
104 joint portion between housing and cover
104a outer edge portion of joint portion between housing and cover
104b inner end portion of joint portion between housing and cover
105 caulking and fixing portion of housing and cover
200 seal structure
200a seal portion
201 liquid seal portion
202 solid seal portion
203 fixing portion
204 groove portion for liquid seal
205 liquid seal material
206 groove portion for solid seal
207 solid seal material
208 electronic component
301 through hole

1. A seal structure comprising:
a seal portion at which a seal material is formed, and a fixing portion that fixes a housing and a cover to each other at a joint portion between the housing and the cover constituting a casing,
wherein the seal portion and the fixing portion are arranged from an outer edge portion side of the joint portion toward an inside of the casing in order of the seal portion and the fixing portion.

2. The seal structure according to claim 1,
wherein the seal portion includes a liquid seal portion obtained by curing a liquid seal material and a solid seal portion at which a solid seal material is disposed, and
the liquid seal portion and the solid seal portion are arranged from the outer edge portion side of the joint portion toward the inside of the casing in order of the liquid seal portion and the solid seal portion.

3. The seal structure according to claim 2,
wherein an inner peripheral surface of the cover and an outer peripheral surface of the housing face each other at the joint portion, and
the fixing portion is formed on an outer peripheral surface of the cover.

4. The seal structure according to claim 3,
wherein the fixing portion fixes the cover to the housing by pressing a plastic deformation portion obtained by plastically deforming the cover against a wall portion of the housing.

5. The seal structure according to claim 4,
wherein the liquid seal portion includes a groove portion for disposing the liquid seal material.

6. The seal structure according to claim 4,
wherein the cover includes a through hole penetrating through the cover, and
the through hole is formed at a position at which an open surface opened on an inner peripheral side of the cover faces the liquid seal portion.

7. The seal structure according to claim 1,
wherein the seal portion includes a liquid seal portion obtained by curing a liquid seal material and a damming portion for damming the liquid seal material, and
the liquid seal portion and the damming portion are arranged from the outer edge portion side of the joint portion toward the inside of the casing in order of the liquid seal portion and the damming portion.

8. An electronic device having an electronic component mounted within a casing constituting the seal structure according to claim 1.
